(19) United States
(12) Patent Application Publication
(10) Pub. No.: US 2026/0314374 A1
(43) Pub. Date: Oct. 8, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chia-Pang KUO, Taoyuan City (TW); Kuei-Wen HUANG, Hsinchu (TW); Chih-Han TSENG, Tainan (TW); Chia-Han LAI, Zhubei (TW); Ya-Lien LEE, Baoshan Township (TW); Hung-Wen SU, Jhubei (TW); Harry CHIEN, Chandler, AZ (US)

(73) Assignee: Taiwan Semiconductor Manufacturing Company, Ltd., Hsinchu (TW)

(21) Appl. No.: 19/322,249

(22) Filed: Sep. 8, 2025

Related U.S. Application Data
(60) Provisional application No. 63/782,982, filed on Apr. 3, 2025.

(51) Int. Cl. H01L 23/532; H01L 21/768; H01L 23/522; H01L 23/528; H10D 30/00; H10D 30/01; H10D 64/23

(52) U.S. Cl. CPC H10W 20/425; H10D 30/019; H10W 20/056; H10W 20/062; H10W 20/064; H10W 20/42; H10W 20/435; H10W 20/498; H10D 30/502; H10D 64/256

(57) ABSTRACT

A method includes forming a semiconductor device over a substrate, and forming an interconnect structure over the semiconductor device. The interconnect structure includes a metal plug including a first metal disposed in a first dielectric layer. A second dielectric layer is formed over the first dielectric layer. The second dielectric layer has an opening therein exposing the metal plug. A nitridation process is performed on the metal plug to form a nitridation layer on the metal plug.

### RELATED APPLICATION

This application claims priority to U.S. Provisional Application No. 63/782,982 filed Apr. 3, 2025, the entire disclosure of which is incorporated herein by reference.

### BACKGROUND

As consumer devices with ever better performance have gotten smaller and smaller in response to consumer demand, the individual components of these devices have necessarily decreased in size as well. Semiconductor devices, which make up major components of consumer devices such as mobile phones, computer tablets, and the like, have become smaller and smaller. The decrease in size of semiconductor devices has been met with advancements in semiconductor manufacturing techniques such as forming connections between semiconductor devices. As device size decreases, resistance in smaller connections increases along with a corresponding increase in heating of the device circuitry. Lower resistance connections are desirable in smaller devices. Lower resistance means less energy is lost as heat when electricity flows through the circuitry, resulting in more efficient operation.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIGS. 1A and 1B show semiconductor devices according to embodiments of the disclosure.

FIGS. 2, 3, 4, 5, 6, 7A, 7B, 8, 9, 10, and 11 show cross sectional views of stages of a method of manufacturing a semiconductor device according to embodiments of the disclosure.

FIGS. 12, 13, 14, 15, 16A, 16B, 17A, and 17B show cross sectional views of stages of a method of manufacturing a semiconductor device according to embodiments of the disclosure.

FIG. 18A shows a cross sectional view of a stage of a method of manufacturing a semiconductor device according to embodiments of the disclosure. FIGS. 18B and 18C are detailed views of a portion of FIG. 18A.

FIGS. 19, 20, 21, and 22 show cross sectional views of stages of a method of manufacturing a semiconductor device according to embodiments of the disclosure.

FIGS. 23 and 24 show semiconductor devices according to embodiments of the disclosure.

FIG. 25 shows a flow chart for a method according to embodiments of the present disclosure.

FIG. 26 shows a flow chart for a method of manufacturing a semiconductor device according to embodiments of the present disclosure.

FIG. 27 shows a flow chart for a method of manufacturing a semiconductor device according to embodiments of the present disclosure.

### DETAILED DESCRIPTION

It is to be understood that the following disclosure provides many different embodiments, or examples, for implementing different features of the disclosure. Specific embodiments or examples of components and arrangements are described below to simplify the present disclosure. These are, of course, merely examples and are not intended to be limiting. For example, dimensions of elements are not limited to the disclosed range or values, but may depend upon process conditions and/or desired properties of the device. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. In addition, the term “made of” may mean either “comprising” or “consisting of.”

Further, in the following fabrication process, there may be one or more additional operations in between the described operations, and the order of operations may be changed. In the present disclosure, a phrase “one of A, B and C” means “A, B and/or C” (A, B, C, A and B, A and C, B and C, or A, B and C), and does not mean one element from A, one element from B and one element from C, unless otherwise described. In the entire disclosure, a source and a drain are interchangeably used, and a source/drain refers to one of or both of the source and the drain. Source/drain structure(s) may refer to a source or a drain, individually or collectively dependent upon the context. In the following embodiments, materials, configurations, dimensions, processes and/or operations as described with respect to one embodiment (e.g., one or more figures) may be employed in the other embodiments, and detailed description thereof may be omitted.

Disclosed embodiments relate to a semiconductor device, in particular, to a semiconductor device having low resistance and low leakage conductive lines or wirings, and their manufacturing methods.

As semiconductor devices are scaled down in size, the space for the electrical connections between the front end of the line (FEOL) devices and back end of the line (BEOL) wiring layers becomes smaller, which increases the contact resistance of the electrical connections. In embodiments of the disclosure, a low resistance connection is provided that does not suffer from an increase in current leakage. Thus, semiconductor devices that can operate at higher power with increased efficiency are provided by embodiments of the present disclosure.

Embodiments of this disclosure relate to metal plug nitridation by BEOL nitrogen impurity doping control. Embodiments include: 1) directly applying nitrogen to the metal plug, for example, NH₃ soaking, and 2) indirect metal nitride nitrogen transfer though an annealing operation. In some embodiments, the annealing is performed in an ambient including hydrogen. In embodiments of the disclosure, the nitridation reduces the amount of BEOL Cu trench to middle end of the line (MEOL) leakage. Embodiments of the disclosure provide advanced node BEOL/MEOL interface low contact resistance and low current and Cu⁺ leakage.

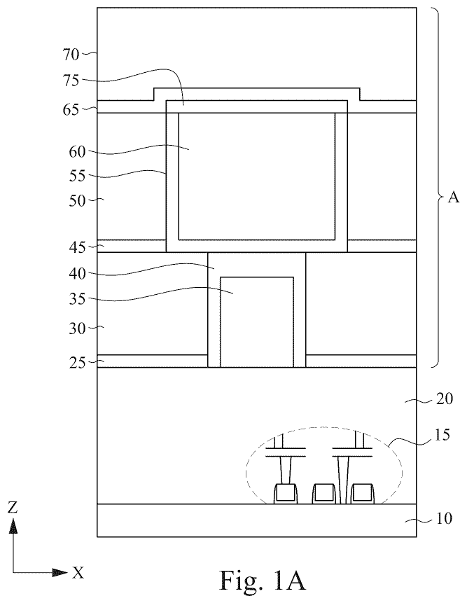

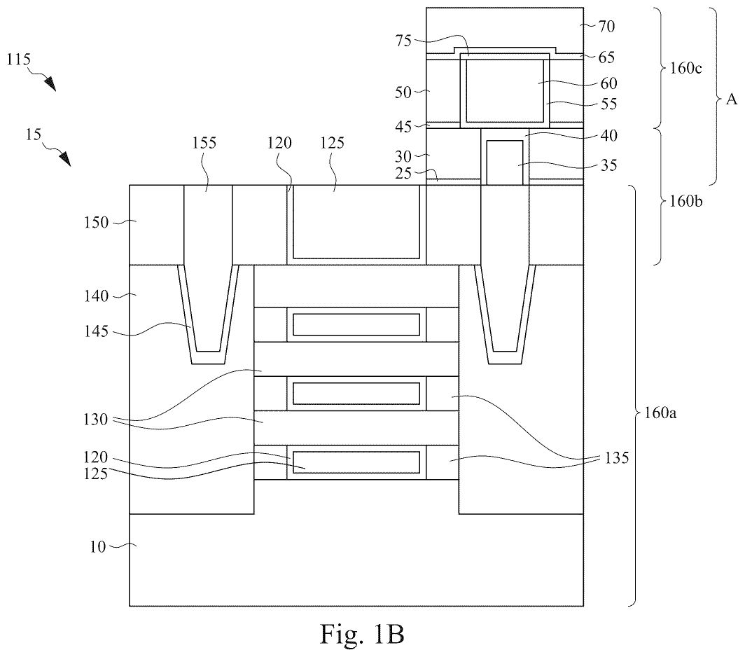

A semiconductor device structure according to embodiments of the disclosure is illustrated in FIG. 1A. The structure includes a first dielectric layer 30 with a first conductive metal contact or plug 35, 40 disposed therein, formed over one or more semiconductor devices or integrated circuit components 15, such as transistors, in a device region 20 disposed over a substrate 10. The conductive metal contact or plug includes a metal inner layer 35 and a metal nitride outer layer 40. In some embodiments, the metal nitride outer layer 40 is a nitride of the metal making up the metal inner layer 35. A second dielectric layer 50 is disposed over the first dielectric layer and the metal contact or plug 35, 40. Another contact 55, 60 is disposed in the second dielectric layer 50. In some embodiments the first metal contact or plug 35, 40 is a middle end of the line (MEOL) contact, and the second metal contact or plug 55, 60 is a BEOL contact.

The semiconductor device components 15 include interconnect structures that include a plurality of interconnect pattern (line) layers having conductive patterns and interconnecting various features in one portion of the die to other features of the die. The interconnect structures are formed of conductive materials such as metal and the semiconductor devices include several interconnect layers in various embodiments. The interconnect layers are often referred to as “metal 0” or “M0” (designating the lowermost interconnect level), “M1,” “M2,” and so on. These designations are used in the art to indicate that the conductive lines interconnect features from various locations in the semiconductor device. In some embodiments, the metal interconnect lines connect an array of transistors to other arrays or other features.

The interconnect layer patterns in different layers are also coupled to one another through vias that extend vertically between one or several interconnect layers. The interconnect layer patterns are coupled to external features and can represent bit lines, signal lines, word lines, and various input/output connections in some embodiments.

Examples of devices that can benefit from one or more embodiments of the present disclosure are semiconductor devices. Such a device, for example, may include static random access memory (SRAM) and/or other logic circuits, passive components such as resistors, capacitors, and inductors, and active components such as P-channel field effect transistors (PFET), N-channel FET (NFET), metal-oxide semiconductor field effect transistors (MOSFET), complementary metal-oxide semiconductor (CMOS) transistors, such as a fin field effect transistors (FinFET) and gate-all-around field effect transistors (GAA FET), bipolar transistors, high voltage transistors, high frequency transistors, other memory cells, and combinations thereof. The semiconductor device may include a plurality of semiconductor devices (e.g., transistors), which may be interconnected. In some embodiments, the semiconductor device components are electrically coupled through underlying interconnection layers including wiring layers and vias formed in dielectric layers, such as an interlayer dielectric (ILD) layer or an intermetal dielectric (IMD) layer. The wiring layers and vias of the interconnection layer may be formed of copper or copper alloys (e.g., AlCu), aluminum, tungsten, nickel, or any other suitable metal. It is understood, however, that the application should not be limited to a particular type of device, except as specifically claimed.

In some embodiments, the substrate 10 includes a single crystalline semiconductor layer on at least its surface portion. The substrate 10 may include a single crystalline semiconductor material such as, but not limited to Si, Ge, SiGe, GaAs, InSb, GaP, GaSb, InAlAs, InGaAs, GaSbP, GaAsSb, and InP. The substrate 10 may include various regions that have been suitably doped with impurities (e.g., p-type or n-type conductivity). The dopants are, for example, boron difluoride (BF₂) for an n-type Fin FET and phosphorus for a p-type Fin FET in some embodiments. In certain embodiments, the substrate 10 is made of crystalline Si.

The substrate 10 may include in its surface region, one or more buffer layers (not shown). The buffer layers can serve to gradually change the lattice constant from that of the substrate to that of the source/drain structures. The buffer layers may be formed from epitaxially grown single crystalline semiconductor materials such as, but not limited to Si, Ge, GeSn, SiGe, GaAs, InSb, GaP, GaSb, InAlAs, InGaAs, GaSbP, GaAsSb, GaN, GaP, and InP. In a particular embodiment, the substrate 10 includes silicon germanium (SiGe) buffer layers epitaxially grown on the silicon substrate 10. The germanium concentration of the SiGe buffer layers may increase from 30 atomic % germanium for the bottom-most buffer layer to 70 atomic % germanium for the top-most buffer layer.

In some embodiments, the semiconductor device 15 in the semiconductor device component region 20 includes a transistor, such as a gate-all-around field effect transistor (GAA FET) as shown in FIG. 1B, but the semiconductor devices 15 of this disclosure are not limited to transistors or GAA FETs. The structure of FIG. 1B includes the structure A of FIG. 1A disposed over the transistor 15. As shown in FIG. 1B, the structure 115 includes a first device portion 160a that is formed in a series of front-end-of-line (FEOL) processes, a second device portion 160b that is formed in a series of middle-end-of-line (MEOL) processes, and a third device portion 160c that is formed in a series of back-end-of-line (BEOL) processes.

The first device portion 160a is configured as a GAA FET, and includes a plurality of semiconductor layers 130 stacked along the Z-direction and configured as stacked channel regions 130. Although three stacked channel regions 130 are shown in FIG. 1B, this disclosure is not so limited and various other embodiments include different numbers of channel regions such that the number of channel regions 130 is ≥1. This embodiment, including a GAA FET, is provided merely as an example, and various other semiconductor devices (e.g., planar field effect transistors (FETs), fin field effect transistors (FinFETs), complementary field-effect transistors (CFETs), and the like) are provided in other embodiments.

The first device portion 160a further includes a gate structure surrounding each of the stacked channel regions 130. The gate structure includes an electrically conductive gate electrode layer 125 that is separated from the stacked channel regions 130 by a gate dielectric layer 120. The first device portion 160a further includes source/drain regions 140 formed on opposite ends of the stacked channel regions 130 along the X-direction and a plurality of dielectric inner spacers 135 that electrically separate the gate structure from the source/drain regions. A source/drain region may refer to either a source region or a drain region. A first interlayer dielectric (ILD) layer 150 having a dielectric constant k3 is formed over the source/drain regions 140. A contact plug 155 is formed in the first ILD layer 150. The contact plug 155 forms an electrically conducting contact with the source/drain region 140. In some embodiments, a silicide layer 145 is disposed between the contact plug 155 and the source/drain region 140. The silicide layer 145 has a higher conductivity than the source/drain region 140, and the contact plug 155 has a higher conductivity than the source/drain region 140. The contact plug is electrically connected to the via contact or plug 35, 40 in structure A.

In some embodiments, the gate dielectric layer 120 is made of a different material than the etch stop layers 25, 45, 65, and the dielectric layers 150, 30, 50, 70. In some embodiments, the etch stop layers 25, 45, 65 are made of a different material than the dielectric layers 150, 30, 50, 70. In some embodiments, at least one of the etch stop layers 25, 45, 65 is thinner than at least one of the dielectric layers 150, 30, 50, 70. In some embodiments, at least one of the etch stop layers 25, 45, 65 is thinner than any of the dielectric layers 150, 30, 50, 70. In some embodiments, the dielectric constant of the gate dielectric layer 120 is greater than the dielectric constant of any of the etch stop layers 25, 45, 65 and any of the dielectric layers 150, 30, 50, 70.

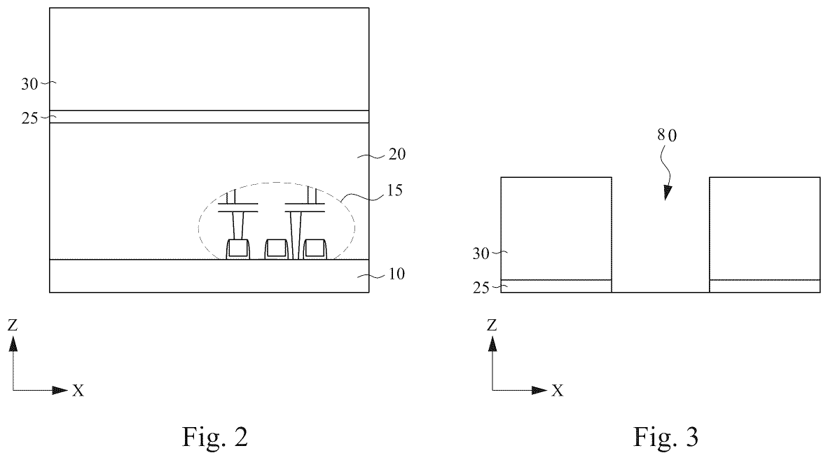

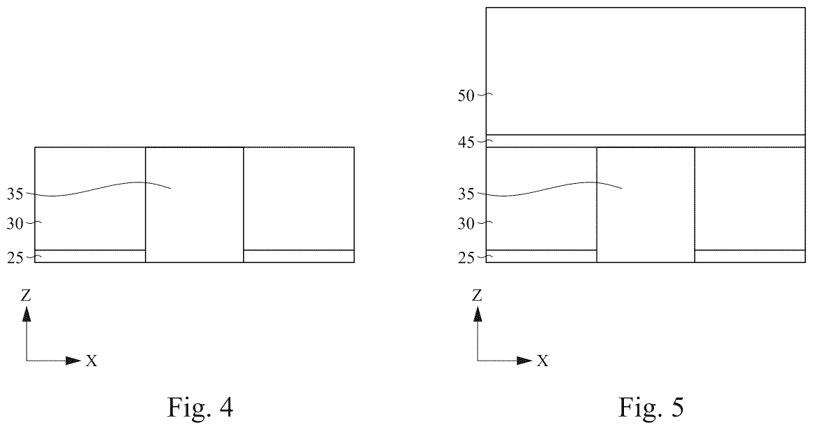

FIGS. 2 to 11 are schematic illustrations showing various stages of manufacturing a semiconductor device according to embodiments of the present disclosure. To simplify the disclosure, the semiconductor device component region 20 and the substrate are not shown in FIGS. 3 to 11. It is understood that additional operations can be provided before, during, and after processes shown by FIGS. 2-11, and some of the operations described below can be replaced or eliminated, for additional embodiments of the method. The order of the operations/processes may be interchangeable.

A first etch stop layer 25 is formed over the semiconductor device component region 20, and first dielectric layer 30 is formed over the etch stop layer 25, as shown in FIG. 2. In some embodiments, the etch stop layer 25 is made of a nitride, such as a silicon nitride, a titanium nitride, or a tantalum nitride. The etch stop layer 25 may be formed by atomic layer deposition (ALD), physical vapor deposition (PVD), chemical vapor deposition (CVD), e-beam evaporation, or any other suitable technique. In some embodiments, the etch stop layer has a thickness ranging from about 5 nm to about 40 nm, and from about 10 nm to about 20 nm in other embodiments. In some embodiments, the first dielectric layer 30 is made of a silicon oxide, a silicon nitride, a silicon oxynitride (SiON), SiOCN, SiCN, a fluorine-doped silicate glass (FSG), or a low-k dielectric material, formed by low pressure CVD (LPCVD), plasma-enhanced CVD (PECVD), PVD, ALD, flowable CVD, or any suitable technique. In some embodiments, the etch stop layer 25 and the first dielectric layer 30 are made of different materials.

As shown in FIG. 3, the dielectric layer 30 and etch stop layer 25 are subsequently etched to form an opening or via 80. The patterning is performed by photolithographic and etching operations in some embodiments. In some embodiments, a photoresist layer is formed over the first dielectric layer 30. The photoresist layer is selectively exposed to actinic radiation, and then the selectively exposed photoresist layer is developed to form a pattern corresponding to the pattern of vias to be formed. The dielectric layer 30 and etch stop layer 25 are etched using suitable etchants using the patterned photoresist layer as a mask to form the via 80. The remaining photoresist layer is subsequently removed using a suitable stripping or plasma ashing operation.

The etching can be performed using wet or dry etching techniques. In some embodiment, plasma etching is used to form the via 80. Different etching gases may be used for etching the different layers. For example, in some embodiments, the first dielectric layer 30 is etched using a fluorocarbon gas, such as CF₄, CHF₃, or C₄F₈; or SF₆; and the etch stop layer 25 is etched using a fluorine-based gas, such as NF₃, CF₄, or SF₆; or a chlorine-based gas, such as Cl₂, HCl, or CCl₄.

A metal is subsequently deposited in the opening or via 80 to form a via contact or plug 35. In some embodiments, the metal is deposited over the top of the first dielectric layer 30, and the excess metal covering the top of the first dielectric layer 30 is removed by an etch-back operation or by a chemical-mechanical polishing (CMP) operation. The metal may be deposited by ALD, PVD, CVD, e-beam evaporation, electroplating, electroless plating, or any other suitable technique. In some embodiments, the metal includes at least one of Mo, W, Ru, Al, Au, Ag, Cu, Mn, Ni, Fe, Pt, Ta, Nb, Zr, Re, or Ir. In an embodiment, the metal is Mo, and in another embodiment, the metal is W. Mo has a lower resistance than W, and Mo costs less than other metals, such as Ru.

Next, a second etch stop layer 45 is formed over the via contact or plug 35, and a second dielectric layer 50 is formed over the second etch stop layer 45, as shown in FIG. 5. In some embodiments, the second etch stop layer 45 is made of a nitride, such as a silicon nitride, a titanium nitride, or a tantalum nitride. The etch stop layer 45 may be formed by ALD, PVD, CVD, e-beam evaporation, or any other suitable technique. In some embodiments, the etch stop layer has a thickness ranging from about 5 nm to about 40 nm, and from about 10 nm to about 20 nm in other embodiments. In some embodiments, the second dielectric layer 50 is made of a silicon oxide, a silicon nitride, SiON, SiOCN, SiCN, a fluorine-doped silicate glass (FSG), or a low-k dielectric material, formed by LPCVD, PECVD, PVD, ALD, flowable CVD, or any suitable technique. In some embodiments, the second dielectric layer 50 is made of a low-k dielectric material, such as a fluorine-doped silicon dioxide, an organosilicate glass (or carbon-doped oxide), porous silicon dioxide, a silsesquioxane, or a spin-on polymer dielectric. In some embodiments, the second etch stop layer 45 and the second dielectric layer 50 are made of different materials.

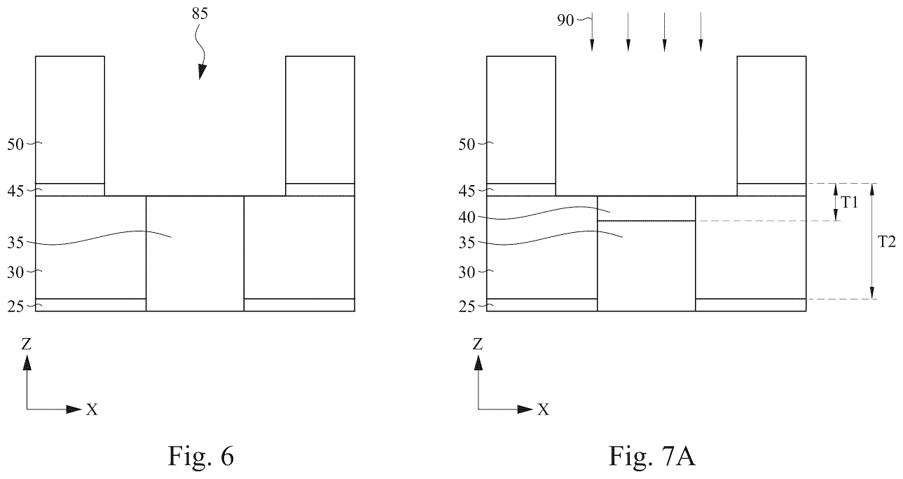

As shown in FIG. 6, the second dielectric layer 50 and second etch stop layer 45 are subsequently etched to form a via or trench 85. The patterning is performed by photolithographic and etching operations in some embodiments. In some embodiments, a photoresist layer is formed over the second dielectric layer 50. The photoresist layer is selectively exposed to actinic radiation, and then the selectively exposed photoresist layer is developed to form a pattern corresponding to the pattern of vias to be formed. The dielectric layer 50 and etch stop layer 45 are etched using suitable etchants using the patterned photoresist layer as a mask to form the via or trench 85. The remaining photoresist layer is subsequently removed using a suitable stripping or plasma ashing operation.

The etching can be performed using wet or dry etching techniques. In some embodiment, plasma etching is used to form the via or trench 85. Different etching gases may be used for etching the different layers. For example, in some embodiments, the second dielectric layer 30 is etched using a fluorocarbon gas, such as CF₄, CHF₃, or C₄F₈; or SF₆; and the etch stop layer 25 is etched using a fluorine-based gas, such as NF₃, CF₄, or SF₆; or a chlorine-based gas, such as Cl₂, HCl, or CCl₄.

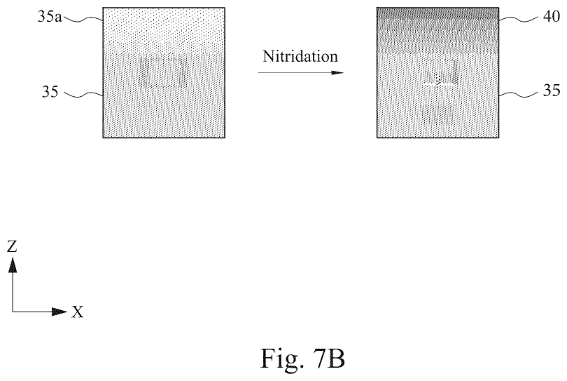

In some embodiments, nitridation of the metal via contact or plug 35 is subsequently performed, as shown in FIG. 7A. In some embodiments, the nitridation operation includes applying a nitrogen-containing gas 90 to the via contact or plug 35 to form a metal nitride layer 40. In some embodiments, the nitrogen-containing gas 90 is NH₃. In some embodiments, the structure is heated while the nitrogen-containing gas 90 is applied. In some embodiments, the structure is heated at a temperature ranging from about 300° C. to about 500° C. during the nitridation operation, and in other embodiments, the nitridation is performed at a temperature greater than about 350° C. in other embodiments, and from about 350° C. to about 450° C. in yet other embodiments. In some embodiments, the nitridation process is performed in a vacuum chamber at an internal pressure of about 0.1 torr to about 100 torr, at a pressure of about 1 torr to about 50 torr in other embodiments, and at a pressure of about 5 torr to about 10 torr in yet other embodiments. In some embodiments, a length of time for the nitridation process ranges from about 10 s to about 60 min, and for about 1 min to about 10 min in other embodiments. In some embodiments, the nitridation of the via or plug 35 forms a nitridation layer 40 in the via or plug extending to a depth T1 ranging from about 1 nm to about 12 nm, and from about 2 nm to about 6 nm in other embodiments. In some embodiments, the thickness T2 of the metal via contact or plug 35 ranges from about 60 nm to about 120 nm, and from about 30 nm to about 60 nm in other embodiments.

At nitridation parameters outside the disclosed ranges, there may be insufficient formation of the metal nitride, there may be too great an increase in the resistivity of the metal via contact or plug, there may be an increase of current leakage, or in increase in copper diffusion from an overlying copper wiring into the metal via contact or plug.

As shown in FIG. 7B, in some embodiments during the nitridation process, the nitrogen-containing gas, such as ammonia, reacts with a native oxide layer 35a on the surface of the metal and converts the metal oxide to a metal nitride. In some embodiments, the nitrogen-containing gas also reacts with the metal. For example, in some embodiments the following reactions take place:

2Mo+2NH₃→2MoN+3H₂,

MoO₃+2NH₃→MoN+3H₂O,

4Mo+2NH₃→2Mo₂N+3H₂, and

8MoO₃+4NH₃→4Mo₂N+6H₂O+9O₂.

In some embodiments, all the native oxide on the exposed upper surface of the metal plug is converted to a metal nitride and some of the elemental metal is converted to the metal nitride. In some embodiments, the converted metal nitride layer is thicker than the native metal oxide layer. In some embodiments, where the metal is molybdenum, most of metal nitride formed is Mo₂N.

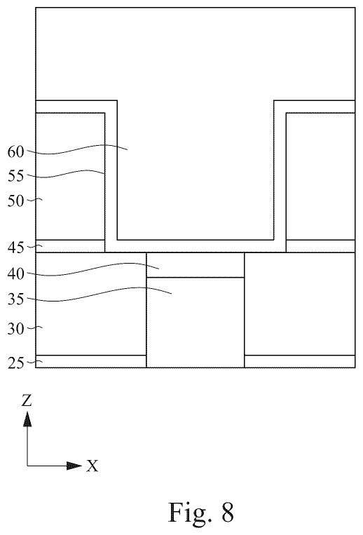

After the nitridation process, a conductive barrier layer 55 and a metal fill layer 60 is formed in the via or trench 85. As shown in FIG. 8, in some embodiments the conductive barrier layer 55 and the metal fill layer 60 extend over the top surface of the second dielectric layer 50. In some embodiments, the conductive barrier layer 55 includes at least one of tantalum, a tantalum nitride, titanium, a titanium nitride, tungsten, a tungsten nitride, niobium, a niobium nitride, zirconium, a zirconium nitride, ruthenium, or nickel. In some embodiments, the fill layer 60 includes at least one of copper, aluminum, tungsten, molybdenum, or alloys thereof. The conductive barrier layer 55 and the fill layer 60 may be formed by ALD, PVD, CVD, e-beam evaporation, electroplating, electroless plating, or any other suitable technique.

In some embodiments, the metal plug 35 is made of Mo. While Mo₂N has a higher resistivity (about 10²±1 μohm-cm) than Mo (about 10¹±0.1), Mo₂N has a lower resistivity than MoO₂ (about 10⁴±10 μohm-cm). Current leakage is less likely to occur at lower dielectric constant (k) values. Mo₂N has a dielectric constant 10<k<20, while MoO₂ has a k of greater than 20. In addition, Mo₂N provides an improved Cu diffusion barrier. For example, Cu⁺ leakage is observed at temperatures below 800° C. for Mo and at temperatures below 600° C. for MoO₂, while Cu⁺ leakage is inhibited up to about 1000° C. for Mo₂N in some embodiments.

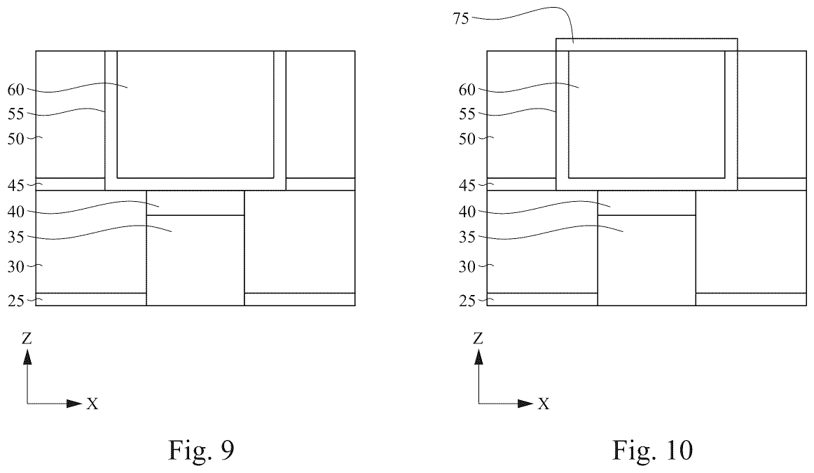

The excess barrier layer and fill layer material covering the top of the second dielectric layer 50 is removed by an etch-back operation or by a CMP operation in some embodiments, as shown in FIG. 9.

In some embodiments, a cap layer 75 is subsequently formed over the conductive barrier layer 55 and the fill layer 60, as shown in FIG. 10. In some embodiments, the cap layer 75 is formed over only the conductive barrier layer 55 and the fill layer 60. In some embodiments, the cap layer 75 does not extend over the second dielectric layer 50. In some embodiments, photolithographic patterning techniques are used to form a mask over the structure before depositing the cap layer. In some embodiments, the cap layer 75 is made of at least one of tantalum, tungsten, cobalt, titanium, molybdenum, a tantalum nitride, a tungsten nitride, a cobalt nitride, a titanium nitride, or a molybdenum nitride. In some embodiments, the cap layer 75 is made of cobalt or molybdenum. The cap layer 75 may be formed by formed by ALD, PVD, CVD, e-beam evaporation, electroplating, electroless plating, or any other suitable technique. In some embodiments, the cap layer 75 has a thickness of about 1 nm to about 10 nm, and from about 2 nm to about 5 nm in other embodiments.

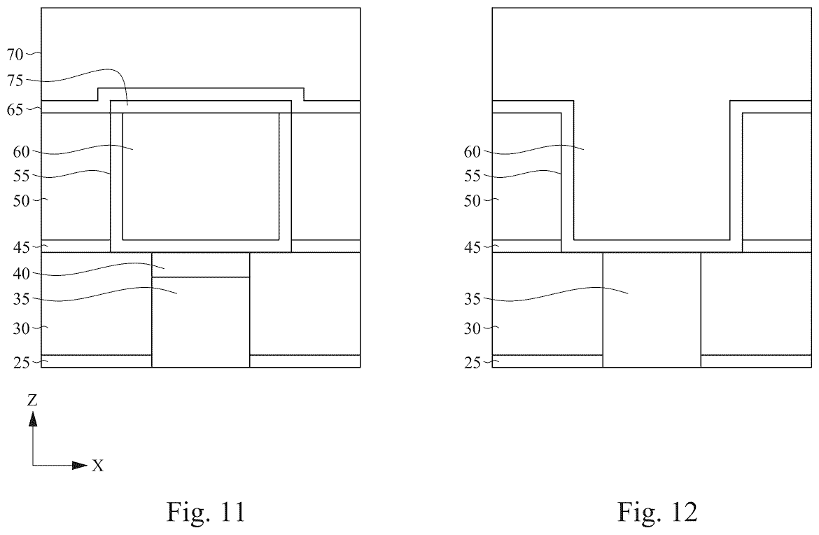

As shown in FIG. 11, a third etch stop layer 65 is formed over the second dielectric layer 50 and/or the cap layer 75. A third dielectric layer 70 is formed over the third etch stop layer 65. In some embodiments, the third etch stop layer 65 is made of a nitride, such as a silicon nitride, a titanium nitride, or a tantalum nitride. The third etch stop layer 65 may be formed by atomic layer ALD, PVD, CVD, e-beam evaporation, or any other suitable technique. In some embodiments, the third etch stop layer has a thickness ranging from about 5 nm to about 40 nm, and from about 10 nm to about 20 nm in other embodiments. In some embodiments, the third dielectric layer 70 is made of a silicon oxide, a silicon nitride, SiON, SiOCN, SiCN, a fluorine-doped silicate glass (FSG), or a low-k dielectric material, formed by LPCVD, PECVD, PVD, ALD, flowable CVD, or any suitable technique. In some embodiments, the second dielectric layer 70 is made of a low-k dielectric material, such as a fluorine-doped silicon dioxide, an organosilicate glass (or carbon-doped oxide), porous silicon dioxide, a silsesquioxane, or a spin-on polymer dielectric. In some embodiments, the third etch stop layer 65 and the third dielectric layer 70 are made of different materials. In some embodiments, the first, second, and third etch stop layers 25, 45, and 65 are made of the same materials, and in other embodiments the first and second etch stop layers 25, 45, the first and third etch stop layers 25, 65, or the second and third etch stop layers 45, 65 are made of the same materials. In some embodiments, the second and third dielectric layers 50, 70 are made of the same materials. In some embodiments, the first dielectric layer 30 is made of a different material than the second and third dielectric layers 50, 70.

FIGS. 12-17B show cross sectional views of stages of a method of manufacturing a semiconductor device according to embodiments of the disclosure. It is understood that additional operations can be provided before, during, and after processes shown by FIGS. 12-17B, and some of the operations described below can be replaced or eliminated, for additional embodiments of the method. The order of the operations/processes may be interchangeable.

The structure of FIG. 12 is formed according to the operations disclosed herein in reference to FIGS. 2-6 followed by forming a conductive barrier layer 55 and a metal fill layer 60. In some embodiments, the conductive barrier layer 55 includes at least one of tantalum, a tantalum nitride, titanium, a titanium nitride, tungsten, a tungsten nitride, niobium, a niobium nitride, zirconium, a zirconium nitride, ruthenium, or nickel. In some embodiments, the fill layer 60 includes at least one of copper, aluminum, tungsten, molybdenum, or alloys thereof. The conductive barrier layer 55 may be formed by ALD, PVD, CVD, or e-beam evaporation, or any other suitable technique. The fill layer 60 may be formed by ALD, PVD, CVD, e-beam evaporation, electroplating, electroless plating, or any other suitable technique.

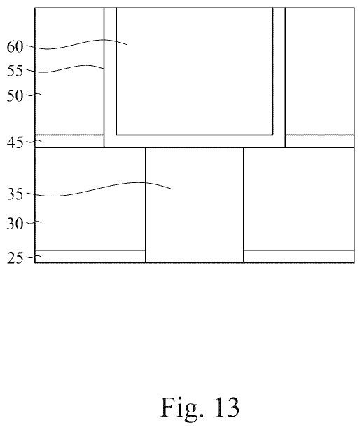

Then, the excess barrier layer material and metal fill layer material are removed in the same manner as disclosed herein in reference to FIG. 9, providing a structure with a planarized upper surface, as shown in FIG. 13.

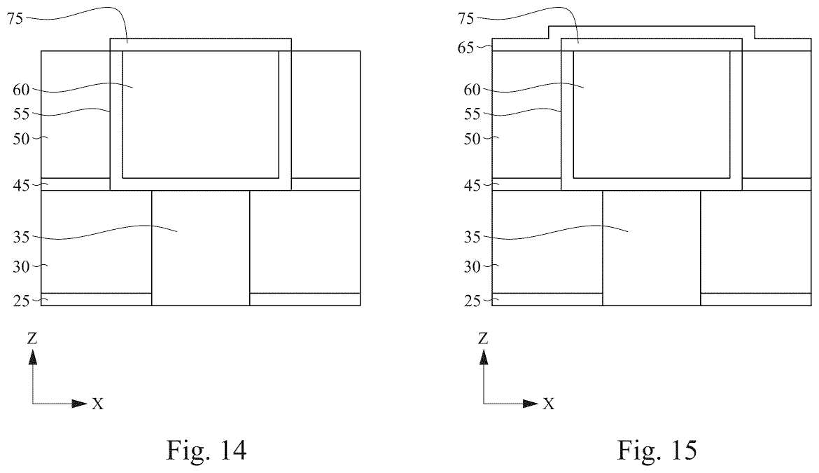

A cap layer 75 is subsequently formed over the conductive barrier layer 55 and the fill layer 60 in some embodiments, as shown in FIG. 14. In some embodiments, the cap layer 75 is formed over only the conductive barrier layer 55 and the fill layer 60. In some embodiments, the cap layer 75 does not extend over the second dielectric layer 50. In some embodiments, photolithographic patterning techniques are used to form a mask over the structure before depositing the cap layer. In some embodiments, the cap layer 75 is made of at least one of a tantalum nitride, a tungsten nitride, a cobalt nitride, a titanium nitride, or a molybdenum nitride. In some embodiments, the cap layer 75 is made of cobalt nitride or molybdenum nitride. The cap layer 75 may be formed by ALD, PVD, CVD, and e-beam evaporation. In some embodiments, the cap layer is formed by a selective CVD co-deposition of a metal and a nitrogen-containing species. For example, in an embodiment, cobalt is co-deposited with NH₃ or a N₂ and H₂ plasma. The concentration of nitrogen in the metal nitride of the cap layer 75 may vary in different embodiments. For example, in some embodiments the cap layer 75 is CoN_{z}, where 0.2≤z≤1. In some embodiments, the cap layer 75 has a thickness of about 1 nm to about 10 nm, and from about 2 nm to about 5 nm in other embodiments.

As shown in FIG. 15, a third etch stop layer 65 is formed over the second dielectric layer 50 and/or cap layer 75. In some embodiments, the third etch stop layer 65 is made of a nitride, such as a silicon nitride, a titanium nitride, or a tantalum nitride. The third etch stop layer 65 may be formed by atomic layer ALD, PVD, CVD, e-beam evaporation, or any other suitable technique. In some embodiments, the third etch stop layer has a thickness ranging from about 5 nm to about 40 nm, and from about 10 nm to about 20 nm in other embodiments. In some embodiments, the third etch stop layer 65 and the third dielectric layer 70 are made of different materials. In some embodiments, the first, second, and third etch stop layers 25, 45, and 65 are made of the same materials, and in other embodiments the first and second etch stop layers 25, 45, the first and third etch stop layers 25, 65, or the second and third etch stop layers 45, 65 are made of the same materials.

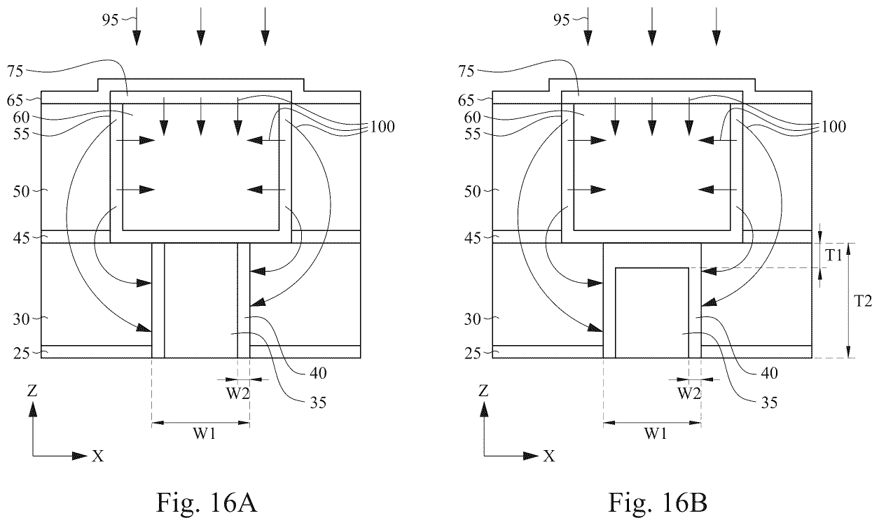

FIGS. 16A and 16B show nitridation processes according to embodiments of the disclosure. In some embodiments, the nitridation is performed by a thermal process causing nitrogen to diffuse from the conductive barrier layer 55 and/or cap layer 75 to the metal via contact or plug 35 to form a metal nitride layer 40. The arrows 100 internal to the structures in FIGS. 16A and 16B illustrate the diffusion of nitrogen during the nitridation process. In some embodiments, the annealing is performed in a hydrogen ambient 95. The hydrogen is mixed with an inert gas, such as helium or argon, in some embodiments. In some embodiments, the nitridation process is performed at a temperature ranging from about 300° C. to about 500° C., and in other embodiments, the nitridation is performed at a temperature greater than about 350° C. in other embodiments, and from about 350° C. to about 450° C. in yet other embodiments. In some embodiments, the nitridation operation is performed in a vacuum chamber at an internal pressure of about 10 torr to about 500 torr, at a pressure of greater than about 50 torr in other embodiments, and at a pressure of about 100 torr to about 200 torr in yet other embodiments. In some embodiments, a length of time for the nitridation operation ranges from about 1 min to about 100 min, and for about 5 min to about 20 min in other embodiments. In some embodiments, the nitridation of the via or plug 35 forms a nitridation layer 40 in the via or plug extending to a thickness T3 on the upper surface of the via or plug ranging from about 0.5 nm to about 6 nm, and from about 1 nm to about 3 nm in other embodiments. In some embodiments, the thickness T2 of the metal via contact or plug 35, 40 ranges from about 60 nm to about 120 nm, and from about 30 nm to about 60 nm in other embodiments. In some embodiments, the width W2 of the metal nitride outer layer on one of the sidewalls ranges from about 0.5 nm to about 6 nm, and from about 1 nm to about 3 nm in other embodiments. In some embodiments, the width W1 of the metal via contact or plug 35, 40 ranges from about 4 nm to about 40 nm, and from about 8 nm to about 20 nm in other embodiments.

In some embodiments, the cobalt nitride cap layer 75 has a reduced thickness after the thermal nitridation depending on the cobalt nitride cap layer impurity level. For example at higher impurity levels (e.g. —C or O), the cap layer is more porous and shrinks more after the thermal nitridation.

At nitridation parameters outside the disclosed ranges, there may be insufficient formation of the metal nitride, there may be too great an increase in the resistivity of the metal via contact or plug, there may be an increase of current leakage, or in increase in copper diffusion from an overlying copper wiring into the metal via contact or plug.

In some embodiments, only the sidewalls of the metal via contact or plug 35 are nitrided to form the metal nitride layer 40, as shown in FIG. 16A, while in other embodiments, the top surface and the sidewalls of the metal via contact or plug 35 are nitrided to form the metal nitride layer 40 as shown in FIG. 16B.

The initial nitride content of the conductive barrier layer 55 in the structure of FIG. 16B is greater than the nitride content of the conductive barrier layer 55 in the structure of FIG. 16A. For example, in an embodiment illustrated by FIG. 16A, the conductive barrier layer 55 as formed is made of a tantalum-rich tantalum nitride having the formula: TaN_{y}, where 0≤y≤0.6, while in an embodiment illustrated by FIG. 16B, the conductive barrier layer 55 as formed is made of tantalum nitride having the formula: TaN_{y}, where 1.3≤y≤1.8. In some embodiments, the conductive barrier layer 55 illustrated in FIG. 16A is metal or metal nitride, such as tantalum or a tantalum nitride formed by PVD or a combination of ALD and PVD. For example, in some embodiments, the conductive barrier layer 55 in the structure of FIG. 16A is formed PVD of tantalum, PVD of a tantalum nitride, or a combination of ALD of a tantalum nitride and PVD of tantalum. In some embodiments, the conductive barrier layer 55 illustrated in FIG. 16B is a metal nitride, such as a tantalum nitride formed by ALD in an inert ambient or in a hydrogen plasma ambient.

In some embodiments, both the conductive barrier layer 55 and the cap layer 75 release nitrogen during the thermal nitridation process, which subsequently diffuses to the metal via contact or plug 35, and reacts with the native oxide on the metal via contact or plug to form the metal nitride layer 40.

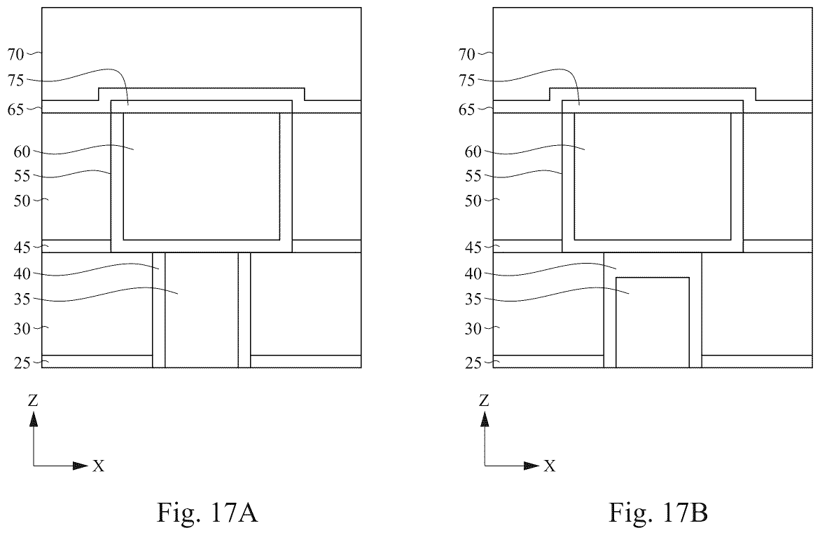

A third etch stop layer 65 and a third dielectric layer 70 are subsequently formed over the structures of FIGS. 16A and 16B, as shown in FIGS. 17A and 17B in some embodiments. The third etch stop layer 65 and the third dielectric layer 70 may be formed of the same materials and the same operations as disclosed herein in reference to FIG. 11.

In an embodiment of the disclosure having a molybdenum plug 35, 40, a copper fill layer 60, tantalum nitride barrier layer 55, a cobalt cap layer 75, and a structure corresponding to FIG. 11, the resistivity of the metal plug 35, 40 was 40%±0.1 greater than a corresponding device that did not undergo the nitridation process. However, the Cu+ leakage was 50% ±0.1 lower than the Cu⁺leakage of the corresponding device that did not undergo the nitridation process.

In an embodiment of the disclosure having a molybdenum plug 35, 40, a copper fill layer 60, a cobalt nitride cap layer 75, and a structure corresponding to FIG. 17A, the resistivity of the metal plug 35, 40 was 10%±0.1 greater than a corresponding device that did not undergo the nitridation process, and the Cu+ leakage was 10% ±0.1 of the Cu⁺ leakage of the corresponding device that did not undergo the nitridation process.

In an embodiment of the disclosure having a molybdenum plug 35, 40, a copper fill layer 60, a tantalum nitride barrier layer 55, a cobalt nitride cap layer 75, and a structure corresponding to FIG. 17B, the resistivity of the metal plug 35, 40 was 20%±0.1 greater than a corresponding device that did not undergo the nitridation process, and the Cu+ leakage was 10%±0.1 of the Cu⁺ leakage of the corresponding device that did not undergo the nitridation process.

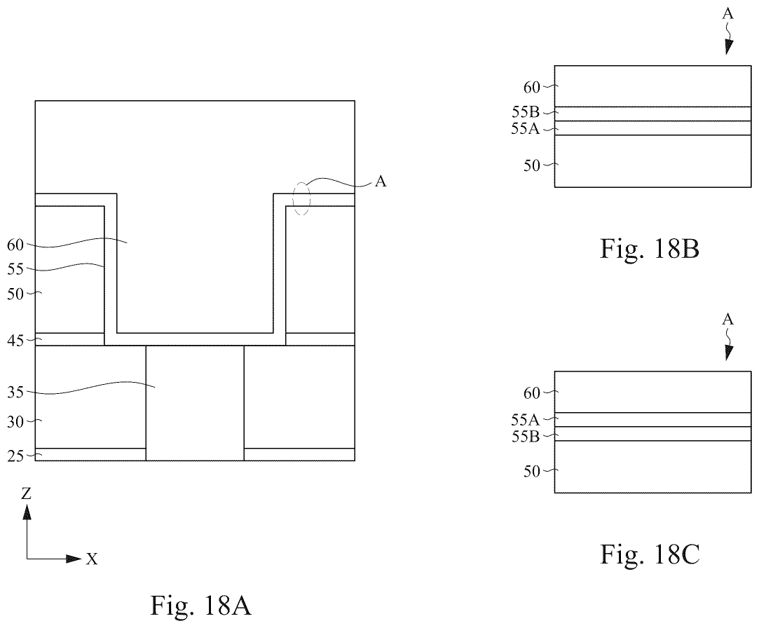

FIG. 18A shows a cross sectional view of a stage of a method of manufacturing a semiconductor device according to embodiments of the disclosure. FIGS. 18B and 18C are detailed views of a portion of FIG. 18A. The structure of FIG. 18A is made in the same manner as the structure of FIG. 12. In some embodiments, the conductive barrier layer 55 includes a plurality of layers. For example, the conductive barrier layer 55 includes a first barrier layer 55A and a second barrier layer 55B, as shown in FIGS. 18B and 18C. The first and second barrier layers 55A and 55B may include a metal layer and a metal nitride layer. For example in FIG. 18B, the first barrier layer 55A is an ALD tantalum nitride layer and the second barrier layer 55B is a PVD tantalum layer. In the embodiment of FIG. 18C, the order of the first and second barrier layers 55A, 55B is reversed. The plurality of conductive barrier layers may also be formed over the structure of FIG. 7A.

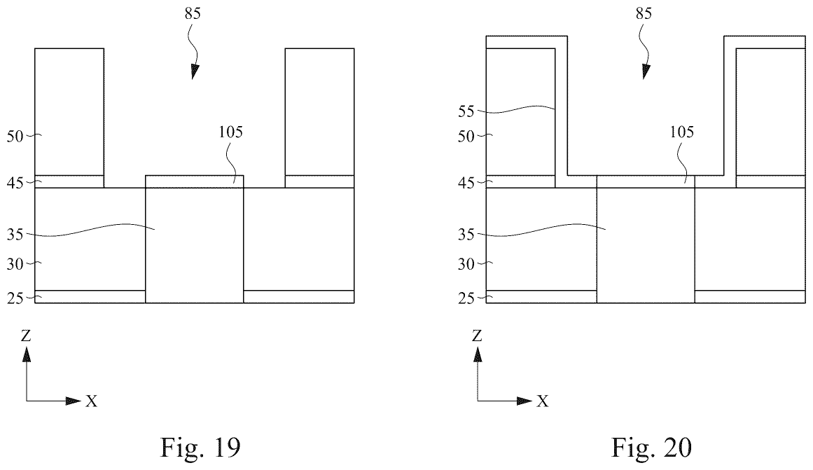

FIGS. 19-22 show cross sectional views of stages of a method of manufacturing a semiconductor device according to embodiments of the disclosure. It is understood that additional operations can be provided before, during, and after processes shown by FIGS. 19-22B, and some of the operations described below can be replaced or eliminated, for additional embodiments of the method. The order of the operations/processes may be interchangeable.

The structure of FIG. 6 is formed according to the operations disclosed herein in reference to FIGS. 2-6 followed by forming a self-assembled monolayer (SAM) 105 over the metal via contact or plug 35, as shown in FIG. 19. In some embodiments, the SAM is formed using an organic compound with an alkyne terminal group. In some embodiments, the alkyne is a C8 to C24 alkyne, and other embodiments the alkyne is a C12-C20 alkyne.

After forming the SAM 105, a conductive barrier layer 55 is formed on the exposed surfaces of the via or trench, as shown in FIG. 20. The conductive barrier layer 55 is formed of any of the materials and by any of the operations for forming a conductive barrier layer disclosed herein. The conductive barrier layer 55 is not formed over the SAM 105. In some embodiments, the conductive barrier layer 55 is a tantalum nitride having a formula TaN_{y}, where 1.3≤y≤1.5.

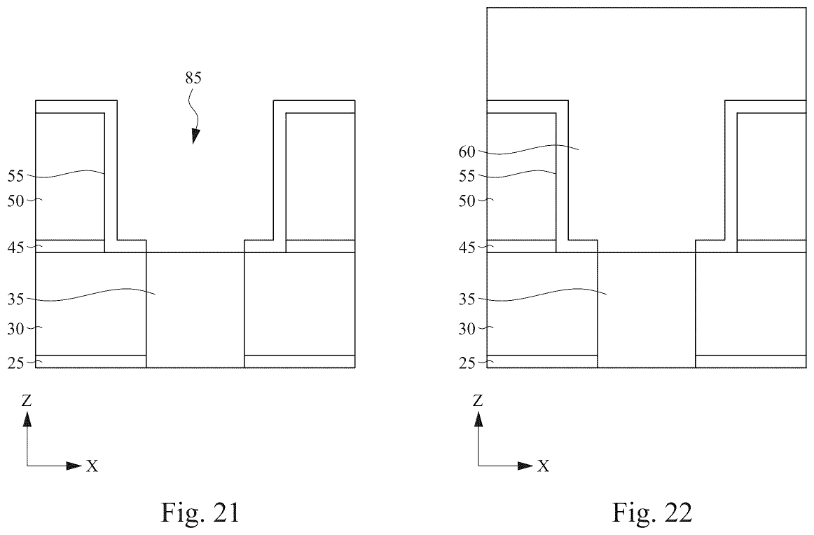

The SAM is subsequently removed, as shown in FIG. 21. The SAM 105 may be removed by an etching operation, such as a piranha etch using a mixture of sulfuric acid and hydrogen peroxide, or by a plasma ashing operation.

Then a metal fill layer 60 is formed over the conductive barrier layer 55 and metal via contact or plug 35, as shown in FIG. 22. The metal fill layer 60 may be formed of any of the materials, or by any of the techniques disclosed herein for forming the metal fill layer. The structure of FIG. 22 may then undergo nitridation, and further processing as disclosed herein in reference to FIGS. 14-17B.

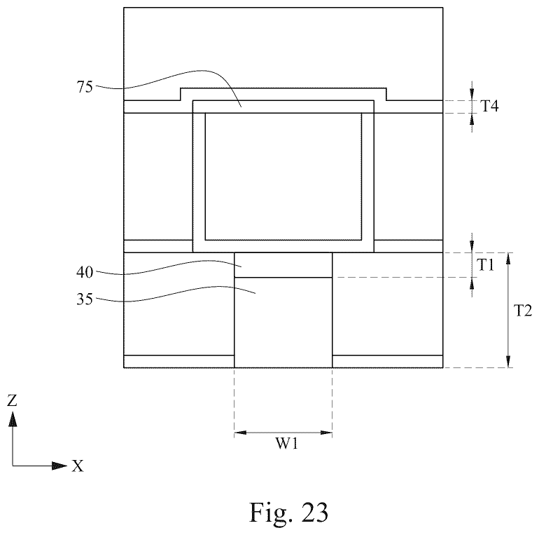

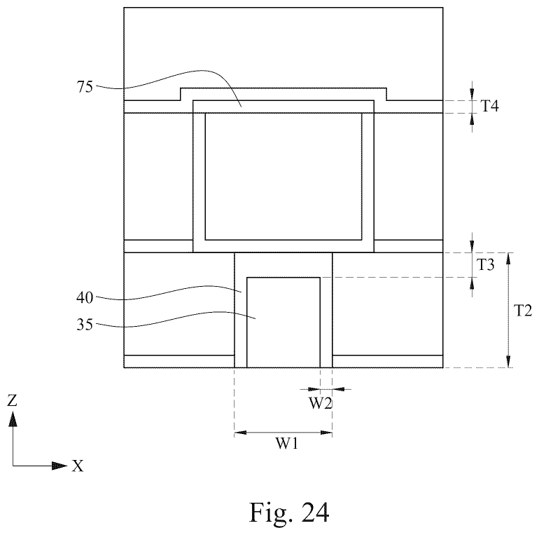

FIGS. 23 and 24 show semiconductor devices according to embodiments of the disclosure. FIG. 23 shows the embodiment where the metal nitride layer 40 is formed on top of the metal via contact or plug 35. As disclosed herein in reference to FIG. 7A, in some embodiments, the thickness T1 of the metal nitride outer layer 40 ranges from about 1 nm to about 12 nm, and from about 2 nm to about 6 nm in other embodiments. In some embodiments, the overall thickness T2 of the metal via contact or plug 35, 40 ranges from about 60 nm to about 120 nm, and from about 30 nm to about 60 nm in other embodiments. In some embodiments, the width W1 of the metal via contact or plug 35 ranges from about 4 nm to about 40 nm, and from about 8 nm to about 20 nm in other embodiments. In some embodiments, the thickness T4 of the cap layer 75 ranges from about 1 nm to about 10 nm, and from about 2 nm to about 5 nm in other embodiments.

In some embodiments, a ratio of the thickness T1 of the metal nitride outer layer 40 to a thickness T2 of the metal via contact or plug 35, 40 ranges from about 0.008 to about 0.2, and T1/T2 ranges from about 0.06 to 0.1 in other embodiments. In some embodiments, a ratio of the thickness T4 of the cap layer 75 to a thickness T1 of the metal nitride outer layer 40 ranges from about 0.08 to about 10, and from about 0.2 to about 2.5 in other embodiments.

FIG. 24 shows the embodiment where the metal nitride layer 40 is formed on top and along sidewalls of the metal via contact or plug 35. As disclosed herein in reference to FIGS. 16A and 16B, in some embodiments the thickness T3 of the metal nitride outer layer 40 on the upper surface of the via or plug 35 ranges from about 0.5 nm to about 6 nm, and from about 1 nm to about 3 nm in other embodiments. In some embodiments, the thickness T2 of the metal via contact or plug 35, 40 ranges from about 60 nm to about 120 nm, and from about 30 nm to about 60 nm in other embodiments. In some embodiments, the width W2 of the metal nitride outer layer on one of the sidewalls ranges from about 0.5 nm to about 6 nm, and from about 1 nm to about 3 nm in other embodiments. In some embodiments, the width W1 of the metal via contact or plug 35, 40 ranges from about 4 nm to about 40 nm, and from about 8 nm to about 20 nm in other embodiments. In some embodiments, the thickness T4 of the cap layer 75 ranges from about 1 nm to about 10 nm, and from about 2 nm to about 5 nm in other embodiments.

In some embodiments, a ratio of the thickness T3 of the metal nitride outer layer 40 on the upper surface of the via contact or plug 35 to a thickness T2 of the metal via contact or plug 35, 40 ranges from about 0.004 to about 0.2, and T3/T2 ranges from about 0.02 to 0.1 in other embodiments. In some embodiments, a ratio of the width W2 of the metal nitride outer layer 40 along the first direction (X direction) to a width W1 of the metal via contact or plug 35, 40 along the first direction (X direction) ranges from about 0.01 to about 0.3, and from about 0.05 to about 0.2 in other embodiments. In some embodiments, a ratio of the thickness T3 of the metal nitride outer layer 40 on the upper surface of the via contact or plug 35 to the width W1 of metal via contact or plug 35, 40 ranges from about 0.01 to about 0.3, and from about 0.05 to about 0.0.2 in other embodiments. In some embodiments, a ratio of the width W2 of the metal nitride outer layer 40 on the sidewalls of the metal via contact or plug 35, 40 to the thickness T2 of the metal via contact or plug 35, 40 ranges from about 0.004 to about 0.2, and ranges from about 0.04 to about 0.1, in other embodiments. In some embodiments, a ratio of the thickness T4 of the cap layer 75 to a thickness T3 of the metal nitride outer layer 40 on the upper surface of the contact via or plug ranges from about 0.08 to about 10, and from about 0.2 to about 2.5 in other embodiments

At metal nitride outer layer 40 and cap layer 75 thickness and widths, and metal nitride outer layer 40, metal via contact or plug 35, 40, and cap layer 75 thickness and/or width ratios outside the disclosed ranges, there may be insufficient formation of the metal nitride, there may be too great an increase in the resistivity of the metal via contact or plug, there may be an increase of current leakage, or in increase in copper diffusion from an overlying copper wiring into the metal via contact or plug.

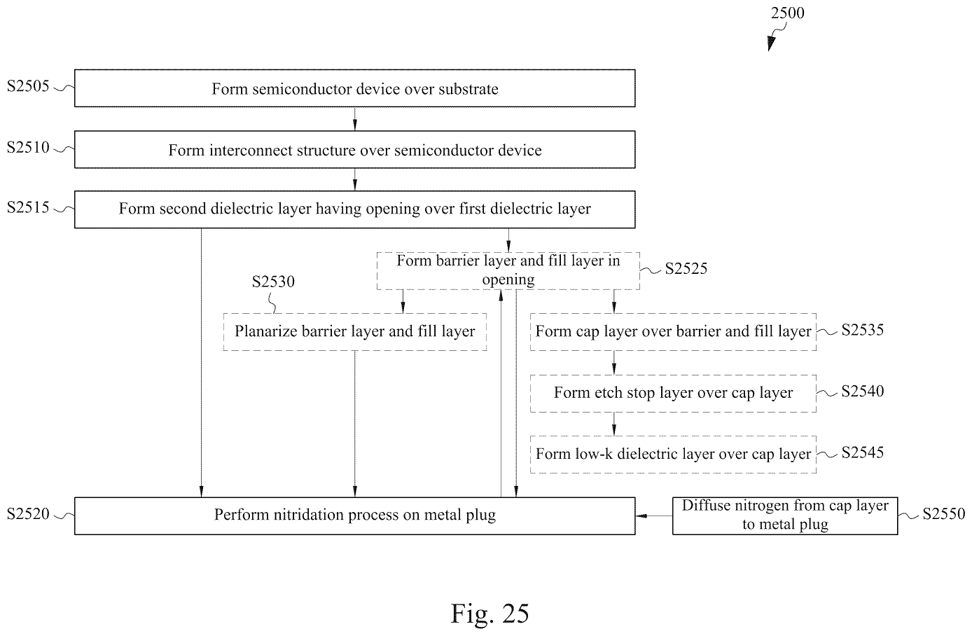

FIG. 25 shows a flow chart for a method 2500 according to embodiments of the present disclosure. The method includes an operation S2505 of forming a semiconductor device 15 over a substrate 10. An interconnect structure is formed over the semiconductor device in operation S2510, wherein the interconnect structure includes a metal plug 35 including a first metal disposed in the first dielectric layer 30. A second dielectric layer 50 having an opening 85 exposing the metal plug 35 is formed over the first dielectric layer 30 in operation S2515. In operation S2520, a nitridation process is performed on the metal plug 35. In some embodiments, a conductive barrier layer 55 and a metal fill layer 60 are formed in the opening 85 in operation S2525. The conductive barrier layer 55 and the metal fill layer 60 are planarized in operation S2530 in some embodiments. In some embodiments, a cap layer 75 including a metal nitride is formed over the conductive barrier layer 55 and metal fill layer 60 is formed in operation S2535. In some embodiments, in operation S2540, an etch stop layer 65 is formed over the cap layer 75, and a low-k dielectric layer 70 is formed over the etch stop layer 65 in operation S2545. In operation S2550, nitrogen is diffused from the cap layer 75 to the metal plug 35 during the nitridation process.

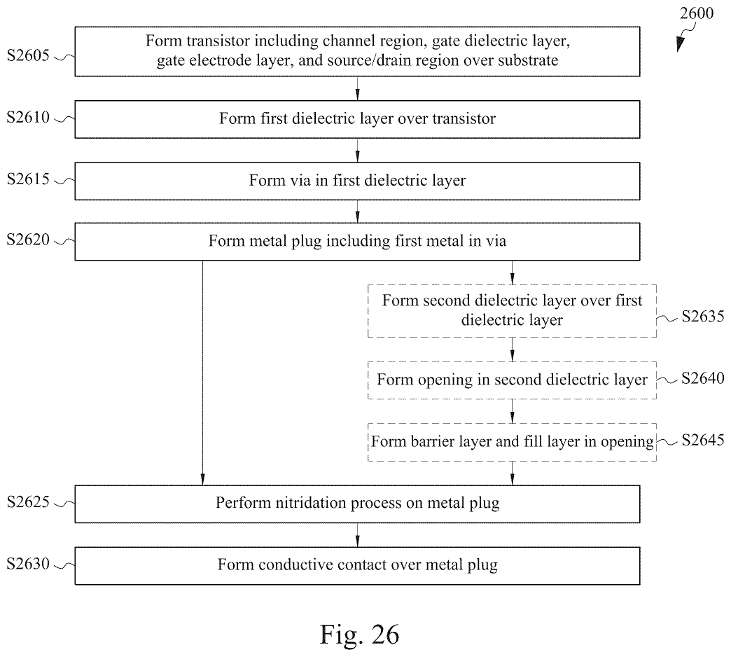

FIG. 26 shows a flow chart for a method 2600 of manufacturing a semiconductor device, including forming at least one transistor 15 including at least one channel region 130, at least one gate dielectric layer 120, at least one gate electrode layer 125, and at least one source/drain region 140 over a substrate 10 in operation S2605. The at least one gate dielectric layer 120 has a first dielectric constant k1. In operation S2610, at first dielectric layer 30 is formed over the transistor 15. The first dielectric layer 30 has a second dielectric constant k2, wherein k1>k2. In operation S2615, a via 80 is formed in the first dielectric layer 30. In operation S2620, a metal plug 35 including a first metal is formed in via 80. Then, in operation S2625, a nitridation process is performed on the metal plug 35. A conductive contact 55, 60 electrically connected to the metal plug 35 is formed over the metal plug in operation S2630. In some embodiments, a second dielectric layer 50 is formed over the first dielectric layer 30 in operation S2635. Then, in some embodiments, an opening 85 is formed in the second dielectric layer 30 in operation S2640, and a conductive barrier layer 55 and metal fill layer 60 are formed in the opening, in operation S2645.

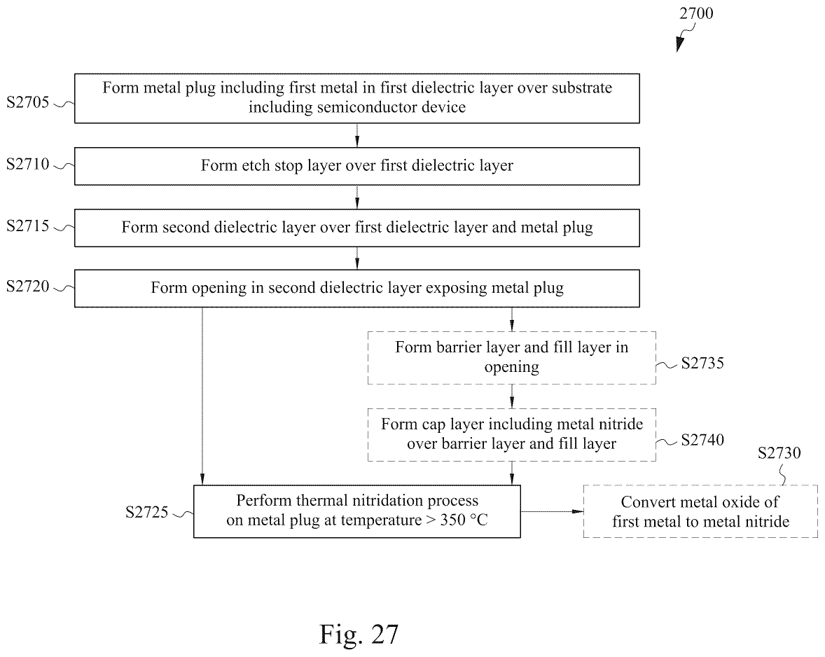

FIG. 27 shows a flow chart for a method 2700 of manufacturing a semiconductor device, including forming a metal plug 35 including a first metal in a first dielectric layer 30 in operation S2705. The first dielectric layer has a first dielectric constant k1. In operation S2710, an etch stop layer 45 have a second dielectric constant k2 is formed over the first dielectric layer 30. In operation S2715, a second dielectric layer 50 having a third dielectric constant k3 is formed over the first dielectric layer 30 and the metal plug 35. The etch stop layer 45 is thinner than the first dielectric layer 30 or the second dielectric layer 50, and k1 is different from k2 or k3. An opening 85 is formed in the second dielectric layer 50 exposing the metal plug 35 in operation S2720. Then, a thermal nitridation process is performed on the metal plug at a temperature greater than 350° C. in operation S2725. In some embodiments, in operation S2730, the thermal nitridation converts a metal oxide of the first metal to a metal nitride. In some embodiments, a conductive barrier layer 55 and a metal fill layer 60 are formed in the opening 85 in operation S2735. Then, in operation S2740, a cap layer 75 including a metal nitride is formed over the barrier layer 55 and the fill layer 60.

Embodiments of the present disclosure provide a semiconductor device having low resistance and reduced current leakage and Cu⁺ leakage. Leakage may occur at native metal oxides. Converting native metal oxides on the plugs to metal nitride reduces the leakage. In some embodiments, Cu⁺ leakage is reduced by 50% to 90% compared to semiconductor devices not undergoing the nitridation processes according to the present disclosure.

It will be understood that not all advantages have been necessarily discussed herein, no particular advantage is required for all embodiments or examples, and other embodiments or examples may offer different advantages.

An embodiment of the disclosure is a method including forming a semiconductor device over a substrate, and forming an interconnect structure over the semiconductor device. The interconnect structure includes a metal plug including a first metal disposed in a first dielectric layer. A second dielectric layer is formed over the first dielectric layer. The second dielectric layer has an opening therein exposing the metal plug. A nitridation process is performed on the metal plug to form a nitridation layer on the metal plug. In an embodiment, the first metal includes at least one of Mo or W. In an embodiment, the method includes forming a barrier layer and a fill layer in the opening. In an embodiment, the method includes planarizing the barrier layer and the fill layer. In an embodiment, the method includes forming a cap layer including a metal nitride over the barrier layer and the fill layer. In an embodiment, the metal nitride includes at least one of a cobalt nitride or a molybdenum nitride. In an embodiment, the method includes forming an etch stop layer over the cap layer and forming a low-k dielectric layer over the etch stop layer. In an embodiment, the nitridation process is performed after forming the cap layer, and nitrogen is diffused from the cap layer to the metal plug during the nitridation process. In an embodiment, the nitridation process is performed before forming the barrier layer and the fill layer. In an embodiment, the nitridation process is performed after forming the barrier layer and the fill layer.

Another embodiment of the disclosure is a method of manufacturing a semiconductor device includes forming at least one transistor including at least one channel region, at least one gate dielectric layer, at least one gate electrode layer, and at least one source/drain region over a substrate. The at least one gate dielectric layer has a first dielectric constant k1. A first dielectric layer having a second dielectric constant k2 is formed over the at least one transistor, wherein k1>k2. A via is formed in the first dielectric layer. A metal plug including a first metal is formed in the via. A nitridation process is performed on the metal plug. A conductive contact electrically connected to the metal plug is formed over the metal plug. In an embodiment, the first metal includes at least one of Mo or W. In an embodiment, forming the conductive contact includes forming a second dielectric layer over the first dielectric layer, forming an opening in the second dielectric layer exposing the metal plug, and forming a barrier layer and a fill layer in the opening. In an embodiment, the barrier layer includes a tantalum nitride or a titanium nitride. In an embodiment, the nitridation process is performed at a temperature ranging from 350° C. to 450° C.

Another embodiment of the disclosure is a method of manufacturing a semiconductor device including forming a metal plug comprising a first metal in a first dielectric layer having a first dielectric constant k1 disposed over a substrate including a semiconductor device. An etch stop layer having a second dielectric constant is formed over the first dielectric layer. A second dielectric layer having a third dielectric constant k3 is formed over the first dielectric layer and metal plug. The etch stop layer is thinner than the first dielectric layer or the second dielectric layer, and k1 is different from k2 or k3. An opening is formed in the second dielectric layer exposing the metal plug, and a thermal nitridation process is performed on the metal plug at a temperature greater than 350° C. In an embodiment, a metal oxide of the first metal is converted to a metal nitride during the thermal nitridation process. In an embodiment, the thermal nitridation process is performed at a pressure ranging from 0.1 Torr to 100 Torr. In an embodiment, the method includes forming a second dielectric layer over the first dielectric layer, the second dielectric layer having an opening therein exposing the metal plug. In an embodiment, the method includes forming a barrier layer and a fill layer in the opening.

Another embodiment of the disclosure is a structure including a semiconductor device disposed on a substrate. A metal plug is disposed in a first dielectric layer disposed over the semiconductor device. The metal plug includes an inner layer including a first metal and an outer layer including a nitride of the first metal. An etch stop layer is disposed over the first dielectric layer, and a second dielectric layer having an opening is disposed over the first dielectric layer. The opening is filled with a barrier layer and a fill layer including a different material than the barrier layer embedded in the barrier layer. The etch stop layer is thinner than first dielectric layer or the second dielectric layer. In an embodiment, the cap layer does not extend over the second dielectric layer. In an embodiment, the cap layer includes at least one of elemental cobalt, elemental molybdenum, a cobalt nitride, or a molybdenum nitride. In an embodiment, the structure includes an etch stop layer disposed over the cap layer and the second dielectric material, wherein the etch stop layer and the second dielectric layer are made of different materials. In an embodiment, a ratio of a thickness T1 of the first metal nitride outer layer to a thickness T2 of the metal plug (T1/T2) ranges from 0.008 to 0.2. In an embodiment, the structure includes a low-k dielectric layer over the etch stop layer, wherein the low-k dielectric layer and the etch stop layer are made of different materials. In an embodiment, the first metal includes at least one of Mo or W. In an embodiment, the barrier layer includes a tantalum nitride or a titanium nitride. In an embodiment, the fill layer includes at least one of copper, aluminum, tungsten, or molybdenum. In an embodiment, the metal plug is electrically coupled to the integrated circuit component.

Another embodiment of the disclosure is a semiconductor device a component layer disposed over a substrate, wherein the component layer comprises at least one integrated circuit component. A first dielectric layer having a first dielectric constant k1 extending along a first direction is disposed over the component layer. A metal via contact penetrates the first dielectric layer and electrically connected to the at least one integrated circuit component. The metal via contact includes an inner layer including a first metal and an outer layer including a nitride of the first metal. An etch stop layer having a second dielectric constant k2 extends along the first direction having a first opening disposed over the first dielectric layer. A second dielectric layer having a third dielectric constant k3 extending along the first direction having a second opening is disposed over the etch stop layer. A conductive barrier layer is disposed in the first opening and the second opening. A metal fill layer is disposed over and embedded in the conductive barrier layer, wherein the metal fill layer is made of a different material than the conductive barrier layer and the first metal. The etch stop layer is made of a different material than the first dielectric layer and the second dielectric layer, and k2 is different than k1 or k3. The etch stop layer is thinner than the first dielectric layer or the second dielectric layer. The first dielectric layer, the etch stop layer, and the second dielectric layer are arranged along a second direction crossing the first direction. In an embodiment, wherein the outer layer including a nitride of the first metal is located between the inner layer including the first metal and the conductive barrier layer, and a ratio of a thickness T1 of the outer layer along the second direction to a thickness T2 of the metal via contact (T1/T2) along the second direction ranges from 0.008 to 0.2. In an embodiment, T1/T2 ranges from 0.06 to 0.1. In an embodiment, the outer layer including a nitride of the first metal is located between the inner layer including the first metal and the conductive barrier layer along the first direction, and a ratio of a width W2 of the outer layer along the first direction to a width W1 of the metal via contact (W2/W1) along the second direction ranges from 0.01 to 0.3. In an embodiment, W1/W2 ranges from 0.05 to 0.2.

Another embodiment of the disclosure is a semiconductor device including a transistor including a channel region, a gate dielectric layer, a gate electrode layer, a source/drain region, a source/drain contact electrically connected to the source/drain region, and a silicide layer disposed between the source/drain region and the source/drain contact disposed over a substrate. The gate dielectric layer has a first dielectric constant k1. The silicide layer has a higher electrical conductivity than the source/drain region, and the source/drain contact has a higher electrical conductivity than the silicide layer. A plug is in a first dielectric layer disposed over the transistor. The plug includes an elemental molybdenum inner layer and a molybdenum nitride outer layer. The first dielectric layer has a second dielectric constant k2, and k1>k2. A second dielectric layer having an opening is disposed over the first dielectric layer. The opening is filled with a nitride barrier layer and a copper fill layer embedded in the nitride barrier layer. The nitride barrier layer is made of different material than the molybdenum nitride outer layer. In an embodiment, the molybdenum nitride outer layer includes MoNₓ, where 0.2≤x≤0.4. In an embodiment, the molybdenum nitride outer layer includes Mo₂N having a face-centered cubic crystal structure. In an embodiment, the semiconductor device includes a cobalt-containing cap layer or a molybdenum-containing cap layer selectively disposed over the barrier layer and the fill layer. In an embodiment, the cobalt-containing cap layer or molybdenum-containing cap layer includes at least one of elemental cobalt, elemental molybdenum, a cobalt nitride, or a molybdenum nitride.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a semiconductor device over a substrate;
forming an interconnect structure over the semiconductor device,
wherein the interconnect structure includes a metal plug comprising a first metal disposed in a first dielectric layer;
forming a second dielectric layer over the first dielectric layer, the second dielectric layer having an opening therein exposing the metal plug; and
performing a nitridation process on the metal plug to form a nitridation layer on the metal plug.

2. The method according to claim 1, wherein the first metal includes at least one of Mo or W.

3. The method according to claim 1, further comprising forming a barrier layer and a fill layer in the opening.
The method according to claim 3, further comprising planarizing the barrier layer and the fill layer.

5. The method according to claim 3, further comprising forming a cap layer including a metal nitride over the barrier layer and the fill layer.

6. The method according to claim 5, wherein the metal nitride includes at least one of a cobalt nitride or a molybdenum nitride.

7. The method according to claim 5, further comprising:
forming an etch stop layer over the cap layer; and
forming a low-k dielectric layer over the etch stop layer.

8. The method according to claim 5, wherein the nitridation process is performed after forming the cap layer, and nitrogen is diffused from the cap layer to the metal plug during the nitridation process.

9. The method according to claim 3, wherein the nitridation process is performed before forming the barrier layer and the fill layer.

10. The method according to claim 3, wherein the nitridation process is performed after forming the barrier layer and the fill layer.

11. A method of manufacturing a semiconductor device, comprising:
forming at least one transistor including at least one channel region, at least one gate dielectric layer, at least one gate electrode layer, and at least one source/drain region over a substrate,
wherein the at least one gate dielectric layer has a first dielectric constant k1;
forming a first dielectric layer having a second dielectric constant k2 over the at least one transistor,
wherein k1>k2;
forming a via in the first dielectric layer;
forming a metal plug including a first metal in the via;
performing a nitridation process on the metal plug; and
forming a conductive contact electrically connected to the metal plug over the metal plug.

12. The method according to claim 11, wherein the first metal includes at least one of Mo or W.

13. The method according to claim 11, wherein forming the conductive contact further comprises:
forming a second dielectric layer over the first dielectric layer;
forming an opening in the second dielectric layer exposing the metal plug; and
forming a barrier layer and a fill layer in the opening.

14. The method according to claim 13, wherein the barrier layer includes a tantalum nitride or a titanium nitride.

15. The method according to claim 11, wherein the nitridation process is performed at a temperature ranging from 350° C. to 450° C.

16. A structure, comprising:
a semiconductor device disposed on a substrate;
a metal plug in a first dielectric layer disposed over the semiconductor device,
wherein the metal plug includes an inner layer including a first metal and an outer layer comprising a nitride of the first metal;
an etch stop layer disposed over the first dielectric layer; and
a second dielectric layer having an opening disposed over the first dielectric layer,
wherein the opening is filled with a barrier layer and a fill layer comprising a different material than the barrier layer embedded in the barrier layer, and
the etch stop layer is thinner than first dielectric layer or the second dielectric layer.

17. The structure of claim 16, further comprising a cap layer disposed over the barrier layer and the fill layer.

18. The structure of claim 17, wherein the cap layer does not extend over the second dielectric layer.

19. The structure of claim 17, wherein the cap layer includes at least one of elemental cobalt, elemental molybdenum, a cobalt nitride, or a molybdenum nitride.

20. The structure of claim 17, wherein a ratio of thickness T1 of the first metal nitride outer layer to a thickness T2 of the metal plug (T1/T2) ranges from 0.008 to 0.2.
